(19) United States
(12) Patent Application Publication
(10) Pub. No.: US 2019/0051707 A1
(43) Pub. Date: Feb. 14, 2019

(54) OLED TOUCH DISPLAY PANEL AND OLED TOUCH DISPLAY

(71) Applicant: WUHAN CHINA STAR OPTOELECTRONICS SEMICONDUCTOR DISPLAY TECHNOLOGY CO., LTD., Wuhan, Hubei (CN)

(72) Inventor: Peng LI, Wuhan, Hubei (CN)

(21) Appl. No.: 15/572,166

(22) PCT Filed: Sep. 6, 2017
(86) PCT No.: PCT/CN2017/100691

§ 371 Date: Nov. 7, 2017

(30) Foreign Application Priority Data
Aug. 14, 2017 (CN) 201710692233.6

(51) Int. Cl. H01L 27/32; H01L 51/52; H01L 51/00; G06F 3/041; G06F 3/044

(52) U.S. Cl. CPC H01L 27/323; H01L 51/5253; G06F 3/044; H01L 27/3244; G06F 3/0412; H01L 51/0097

(57) ABSTRACT

The present disclosure provides an organic light emitting diode (OLED) touch display panel and an organic light emitting diode (OLED) touch display. The OLED touch display panel includes an array substrate, an OLED layer disposed on the array substrate, an encapsulation layer disposed on the OLED layer and the array substrate, and a touch structural layer disposed on the encapsulation layer. According to the present disclosure, the touch structural layer is directly disposed on the encapsulation layer without the need to use a specific glass substrate, therefore reducing thickness of the OLED touch display panel.

### FIELD OF THE DISCLOSURE

The present disclosure relates to the field of organic light emitting diode (OLED) displays, and more particularly to an OLED touch display panel and an OLED touch display.

### BACKGROUND

Generally, a flexible OLED touch display screen includes a flexible OLED display screen and a touch screen disposed on the flexible OLED display screen. The touch screen includes a glass substrate and a touch circuit disposed on the glass substrate. However, such design where the touch screen is disposed on the flexible OLED display screen increases thickness of the flexible OLED touch display screen.

Therefore, there is a need to solve the problems encountered by the prior art

### SUMMARY OF THE DISCLOSURE

One of the objectives of the present disclosure is to provide an OLED touch display panel and an OLED touch display for reducing the thickness of the OLED touch display panel.

To solve the above-mentioned problems, the present disclosure provides the following technical schemes.

The present disclosure provides an organic light emitting diode (OLED) touch display panel, comprising:

an array substrate;

an OLED layer disposed on the array substrate;

an encapsulation layer disposed on the OLED layer and the array substrate; and

a touch structural layer disposed on the encapsulation layer.

In the OLED touch display panel of the present disclosure,

the touch structural layer has a projected capacitive touch structure, wherein the touch structural layer includes a first conductive layer, a first insulation layer, a second conductive layer, and a second insulation layer; and

the first conductive layer is disposed on the encapsulation layer, the first insulation layer is disposed on the first conductive layer, the second conductive layer is disposed on the first insulation layer, and the second insulation layer is disposed on the second conductive layer.

In the OLED touch display panel of the present disclosure,

the array substrate includes a flexible substrate, a driving circuit layer disposed on the flexible layer, and a pixel structural layer;

the pixel structural layer includes a pixel circuit layer and an OLED anode electrode layer, wherein the OLED anode electrode layer is disposed on the pixel circuit layer and the pixel circuit layer is disposed on the flexible substrate; and

the driving circuit layer is electrically connected to the first conductive layer and the pixel structural layer, wherein the driving circuit layer is configured to drive the pixel structural layer and the first conductive layer.

In the OLED touch display panel of the present disclosure, the encapsulation layer includes a through-hole to expose the driving circuit layer of the array substrate, and the first conductive layer contacts and is electrically connected to the driving circuit layer via the through-hole.

In the OLED touch display panel of the present disclosure, the first conductive layer and the second conductive layer are made of a transparent conductive material.

In the OLED touch display panel of the present disclosure, the touch structural layer has a lateral capacitive touch structure, wherein the touch structural layer includes a third conductive layer disposed on the encapsulation layer and a fourth insulation layer disposed on the third conductive layer.

In the OLED touch display panel of the present disclosure, the OLED touch display panel further comprises a polarizer plate and a first bonding layer, wherein the first bonding layer is disposed on the touch structural layer, and the polarizer plate is disposed on the bonding layer.

In the OLED touch display panel of the present disclosure, the OLED touch display panel further comprises a cover plate and a second bonding layer, wherein the second bonding layer is disposed on the polarizer plate, and the cover plate is disposed on the second bonding layer.

In the OLED touch display panel of the present disclosure,

the OLED layer includes a hole injection layer, a electroluminescent layer, an electron injection layer, and a cathode electrode layer; and

the hole injection layer is disposed on the array substrate, the electroluminescent layer is disposed on the hole injection layer, the electron injection layer is disposed on the electroluminescent layer, and the cathode electrode layer is disposed on the electron injection layer.

Additionally, the present disclosure provides an organic light emitting diode (OLED) touch display, comprising the OLED touch display panel as described above.

Compared to conventional techniques, the present disclosure is characterized by directly disposing the touch structural layer on the encapsulation layer without the need to use a specific glass substrate, therefore the thickness of the OLED touch display panel is reduced.

### BRIEF DESCRIPTION OF THE DRAWINGS

FIG. 1 is a cross-sectional view of a display area of an OLED touch display panel according to a preferred embodiment of the present disclosure.

FIG. 2 is a cross-sectional view of an output end of a touch driving circuit layer in a non-display area of an OLED touch display panel according to a preferred embodiment of the present disclosure.

FIG. 3 is a cross-sectional view of a touch structural layer according to a preferred embodiment of the present disclosure.

FIG. 4 is a cross-sectional view of a touch structural layer according to another preferred embodiment of the present disclosure.

### DETAILED DESCRIPTION

The following embodiments refer to the accompanying drawings for exemplifying specific implementable embodiments of the present disclosure. Moreover, directional terms described by the present disclosure, such as upper, lower, front, back, left, right, inner, outer, side, etc., are only directions by referring to the accompanying drawings, and thus the used directional terms are used to describe and understand the present disclosure, but the present disclosure is not limited thereto. In the drawings, the same reference symbol represents the same or similar components.

In the drawings, similar elements are represented by similar reference numerals.

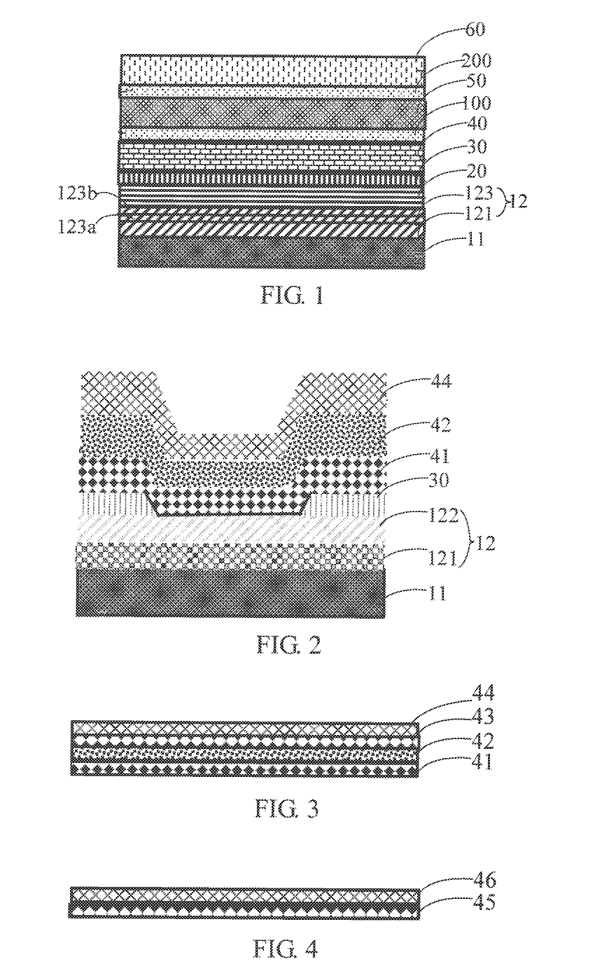

Please refer to FIGS. 1 and 2. FIG. 1 is a cross-sectional view of a display area of an OLED touch display panel according to a preferred embodiment of the present disclosure. FIG. 2 is a cross-sectional view of an output end of a touch driving circuit layer in a non-display area of an OLED touch display panel according to a preferred embodiment of the present disclosure.

The OLED touch display panel includes an array substrate 10, an OLED layer 20, an encapsulation layer 30, a touch structural layer 40, a polarizer plate 50, and a cover plate 60. The OLED layer 20 is disposed on the array substrate 10. The encapsulation layer 30 is disposed on the OLED layer 20 and the array substrate 10. The touch structural layer 40 is disposed on the encapsulation layer 30. The polarizer plate 50 is disposed on the touch structural layer 40. The cover plate 60 is disposed on the polarizer plate 50.

In this embodiment of the present disclosure, the array substrate 10 includes a flexible substrate 11 and an array structure 12 disposed on the flexible substrate 11. The array structure 12 includes a third insulation layer 121, a driving circuit layer 122 (as shown in FIG. 2), and a pixel structural layer 123 (as shown in FIG. 1). The third insulation layer 121 is disposed on the flexible substrate 11. The driving circuit layer 122 and the pixel structural layer 123 are both disposed on the third insulation layer 121. The encapsulation layer 30 is disposed on the driving circuit layer 122 and the OLED layer 20. The driving circuit layer 122 is located in a non-display area of the OLED touch display panel. The pixel structural layer 123 is located in a display area of the OLED touch display panel.

The third insulation layer 121 is made of a material, such as silicon nitride and silicon oxide, and is formed by a chemical vapor deposition process. The driving circuit layer 122 and the pixel structural layer 123 are both formed by a low temperature polysilicon thin-film transistor (LTPS TFT) technique.

The OLED layer 20 is disposed on the array structure 12. Specifically, the OLED layer 20 is between the encapsulation layer 30 and the pixel structural layer 123. The pixel structural layer 123 includes a pixel circuit layer 123a and an OLED anode electrode layer 123b. The pixel circuit layer 123a is disposed on the third insulation layer 121. The OLED anode electrode layer 123b is disposed on the pixel circuit layer 123a. The OLED layer 20 includes a hole injection layer, a electroluminescent layer, an electron injection layer, and a cathode electrode layer. The hole injection layer is disposed on the OLED anode electrode layer. The electroluminescent layer is disposed on the hole injection layer. The electron injection layer is disposed on the electroluminescent layer. The cathode electrode layer is disposed on the electron injection layer.

The encapsulation layer 30 is a thin-film encapsulation layer, which is made of a hydrophobic material and has a property of blocking oxygen gas. It is understood that the encapsulation layer 30 can also consist of a silicon nitride insulation layer and a thin-film encapsulation layer. The encapsulation layer 30 covers the driving circuit layer 122 of the array structure 12 and the cathode electrode layer of the OLED layer 20.

The OLED touch display panel further includes a first bonding layer 100 configured for connecting the polarizer plate to the touch structural layer. The first bonding layer 100 is disposed on the touch structural layer. The polarizer plate is disposed on the first bonding layer 100.

The cover plate 60 is a glass cover plate, or is a thin film with good scratch resisting ability. The OLED touch display panel further includes a second bonding layer 200 configured for connecting the polarizer plate 50 to the cover plate 60. The second bonding layer 200 is disposed on the polarizer plate 50. The cover plate 60 is disposed on the second bonding layer 200.

The touch structural layer 40 is configured for receiving touch operation signals triggered by the users.

In this embodiment, the driving circuit layer 122 includes a display driving circuit layer and a touch driving circuit layer. The display driving circuit layer and the touch driving circuit layer are at the same height level. The touch driving circuit layer is electrically connected to the touch structural layer 40, and the display driving circuit layer is electrically connected to the pixel structural layer 123. The driving circuit layer 122 is configured for driving the pixel structural layer 123 and the touch structural layer 40.

In this embodiment, the touch driving circuit layer of the driving circuit layer 122 on the array substrate 10 can be alternatively used to drive the touch structural layer 40. The touch structural layer 40 is electrically connected to the output end of the touch driving circuit layer of the driving circuit layer 122 (see FIG. 2).

Please refer to FIG. 3, which shows one preferred embodiment where the touch structural layer 40 has a projected capacitive touch structure. The touch structural layer 40 includes a first conductive layer 41, a first insulation layer 42, a second conductive layer 43, and a second insulation layer 44. The first conductive layer 41 is disposed on the encapsulation layer 30. The first insulation layer 42 is disposed on the first conductive layer 41. The second conductive layer 43 is disposed on the first insulation layer 42. The second insulation layer 44 is disposed on the second conductive layer 43.

The first conductive layer 41 and the second conductive layer 43 are both made of a transparent conductive material, such as indium tin oxide (ITO). In the manufacturing process of the display, a physical vapor deposition process is used to form the first conductive layer 41 on the encapsulation layer 30, and then the first conductive layer 41 is patterned by a lithographic process to form a plurality of first touch electrodes. Similarly, a physical vapor deposition process is used to form the second conductive layer 43 on the first insulation layer 42, and then the second conductive layer 43 is patterned by a lithographic process to form a plurality of second touch electrodes. A plurality of touch capacitors are thus formed with each of the first touch electrodes corresponding to and being opposite to one of the second touch electrodes.

The first insulation layer 42 and the second conductive layer 43 can be made of an insulation material, such as silicon nitride or silicon oxide, and can be formed by a chemical vapor deposition process.

To achieve connection between the first conductive layer 41 and the output end of the touch driving circuit layer of the driving circuit layer 122, a through-hole 300 is formed in the encapsulation layer 30 at location where the output end of the touch driving circuit layer of the driving circuit layer 122 is located. The first conductive layer 41 contacts and is electrically connected to the output end of the touch driving circuit layer of the driving circuit layer 122 via the through-hole 300.

Please also refer to FIG. 4. In other embodiments, the touch structural layer 40 has a lateral capacitive touch structure. The touch structural layer 40 includes a third conductive layer 45 disposed on the encapsulation layer 30 and a fourth insulation layer 46 disposed on the third conductive layer 45. The third conductive layer 45 is made of a transparent conductive material, such as indium tin oxide (ITO). In the manufacturing process of the display, a physical vapor deposition process is used to form the third conductive layer 45 on the encapsulation layer 30, and then the third conductive layer 45 is patterned by a lithographic process to form a plurality of touch electrodes. The touch electrodes and other neighboring touch electrodes constitute a plurality of capacitors, which can be used to sense the touch operations of the users.

Compared to conventional techniques, the present disclosure is characterized by directly disposing the touch structural layer on the encapsulation layer without the need to use a specific glass substrate, therefore the thickness of the OLED touch display panel is reduced.

Additionally, the present disclosure provides an OLED touch display, comprising the OLED touch display as described in the above embodiments.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. An organic light emitting diode (OLED) touch display panel, comprising:
an array substrate;
an OLED layer disposed on the array substrate;
an encapsulation layer disposed on the OLED layer and the array substrate; and
a touch structural layer disposed on the encapsulation layer.

2. The OLED touch display panel according to claim 1, wherein
the touch structural layer has a projected capacitive touch structure, wherein the touch structural layer includes a first conductive layer, a first insulation layer, a second conductive layer, and a second insulation layer; and
the first conductive layer is disposed on the encapsulation layer, the first insulation layer is disposed on the first conductive layer, the second conductive layer is disposed on the first insulation layer, and the second insulation layer is disposed on the second conductive layer.

3. The OLED touch display panel according to claim 2, wherein
the array substrate includes a flexible substrate, a driving circuit layer disposed on the flexible layer, and a pixel structural layer;
the pixel structural layer includes a pixel circuit layer and an OLED anode electrode layer, wherein the OLED anode electrode layer is disposed on the pixel circuit layer and the pixel circuit layer is disposed on the flexible substrate; and
the driving circuit layer is electrically connected to the first conductive layer and the pixel structural layer, wherein the driving circuit layer is configured to drive the pixel structural layer and the first conductive layer.

4. The OLED touch display panel according to claim 3, wherein the encapsulation layer includes a through-hole to expose the driving circuit layer of the array substrate, and the first conductive layer contacts and is electrically connected to the driving circuit layer via the through-hole.

5. The OLED touch display panel according to claim 2, wherein the first conductive layer and the second conductive layer are made of a transparent conductive material.

6. The OLED touch display panel according to claim 3, wherein the first conductive layer and the second conductive layer are made of a transparent conductive material.

7. The OLED touch display panel according to claim 4, wherein the first conductive layer and the second conductive layer are made of a transparent conductive material.

8. The OLED touch display panel according to claim 1, wherein the touch structural layer has a lateral capacitive touch structure, wherein the touch structural layer includes a third conductive layer disposed on the encapsulation layer and a fourth insulation layer disposed on the third conductive layer.

9. The OLED touch display panel according to claim 2, further comprising a polarizer plate and a first bonding layer, wherein the first bonding layer is disposed on the touch structural layer, and the polarizer plate is disposed on the bonding layer.

10. The OLED touch display panel according to claim 9, further comprising a cover plate and a second bonding layer, wherein the second bonding layer is disposed on the polarizer plate, and the cover plate is disposed on the second bonding layer.

11. The OLED touch display panel according to claim 1, wherein
the OLED layer includes a hole injection layer, a electroluminescent layer, an electron injection layer, and a cathode electrode layer; and
the hole injection layer is disposed on the array substrate, the electroluminescent layer is disposed on the hole injection layer, the electron injection layer is disposed on the electroluminescent layer, and the cathode electrode layer is disposed on the electron injection layer.

12. An organic light emitting diode (OLED) touch display panel, comprising:
an array substrate;
an OLED layer disposed on the array substrate;
an encapsulation layer disposed on the OLED layer and the array substrate; and
a touch structural layer disposed on the encapsulation layer;
wherein:
the touch structural layer has a projected capacitive touch structure;
the touch structural layer includes a first conductive layer, a first insulation layer, a second conductive layer, and a second insulation layer,
the first conductive layer is disposed on the encapsulation layer, the first insulation layer is disposed on the first conductive layer, the second conductive layer is disposed on the first insulation layer, and the second insulation layer is disposed on the second conductive layer;
the array substrate includes a flexible substrate, a driving circuit layer disposed on the flexible layer, and a pixel structural layer;
the pixel structural layer includes a pixel circuit layer and an OLED anode electrode layer, wherein the OLED anode electrode layer is disposed on the pixel circuit layer and the pixel circuit layer is disposed on the flexible substrate;
the driving circuit layer is electrically connected to the first conductive layer and the pixel structural layer, wherein the driving circuit layer is configured to drive the pixel structural layer and the first conductive layer;
the encapsulation layer includes a through-hole to expose the driving circuit layer of the array substrate, and the first conductive layer contacts and is electrically connected to the driving circuit layer via the through-hole;
the first conductive layer and the second conductive layer are made of a transparent conductive material;
the touch structural layer has a lateral capacitive touch structure, wherein the touch structural layer includes a third conductive layer disposed on the encapsulation layer and a fourth insulation layer disposed on the third conductive layer;
the OLED layer includes a hole injection layer, a electroluminescent layer, an electron injection layer, and a cathode electrode layer; and
the hole injection layer is disposed on the array substrate, the electroluminescent layer is disposed on the hole injection layer, the electron injection layer is disposed on the electroluminescent layer, and the cathode electrode layer is disposed on the electron injection layer.

13. An organic light emitting diode (OLED) touch display, comprising the OLED touch display panel according to claim 1.
